(19) United States
(12) Patent Application Publication
(10) Pub. No.: US 2024/0178874 A1
(43) Pub. Date: May 30, 2024

(54) ANTENNA DEVICE

(71) Applicant: Mitsubishi Electric Corporation, Tokyo (JP)

(72) Inventors: Toru FUKASAWA, Tokyo (JP); Akimichi HIROTA, Tokyo (JP)

(73) Assignee: Mitsubishi Electric Corporation, Tokyo (JP)

(21) Appl. No.: 18/434,125

(22) Filed: Feb. 6, 2024

Related U.S. Application Data
(63) Continuation of application No. PCT/JP2021/039737, filed on Oct. 28, 2021.

(51) Int. Cl. H04B 1/40; H01P 5/12; H03F 1/02

(52) U.S. Cl. CPC H04B 1/40; H01P 5/12; H03F 1/0288

(57) ABSTRACT

An antenna device is configured to include: a divider circuit including an input/output terminal and a plurality of divider terminals; a plurality of matching circuits including one ends connected with the divider terminals; and a plurality of antenna elements connected with other ends of the matching circuits. Furthermore, the matching circuits are lossless circuits each having only an inductance component and a capacitance component, and the divider circuit is a lossless circuit whose characteristic impedance is indicated only by the inductance component and the capacitance component.

### CROSS REFERENCE TO RELATED APPLICATIONS

This application is a Continuation of PCT International Application No. PCT/JP2021/039737 filed on Oct. 28, 2021, which is hereby expressly incorporated by reference into the present application.

### TECHNICAL FIELD

The present disclosure relates to an antenna device that includes a plurality of antenna elements.

### BACKGROUND ART

There is an antenna device that includes N (N represents an integer equal to or more than two) antenna elements (see Patent Literature 1). The antenna device includes a Wilkinson power divider that divides power of a transmission signal to the N antenna elements.

### CITATION LIST

### Patent Literatures

Patent Literature 1: JP 2016-152560 A

### SUMMARY OF INVENTION

### Technical Problem

The Wilkinson power divider of the antenna device disclosed in Patent Literature 1 has a resistance component whose loss cannot be neglected. Part of power of reflected waves from antenna elements may be consumed by the resistance component of the Wilkinson power divider. Hence, there has been a problem that a gain of the entire antenna device may be lowered.

The present disclosure has been made to solve the above problem, and an object of the present disclosure is to obtain an antenna device that can suppress consumption of power of a reflected wave, and prevent a gain from lowering.

### Solution to Problem

An antenna device according to the present disclosure includes: a divider circuit including an input/output terminal and a plurality of divider terminals; a plurality of matching circuits respectively having one ends connected with the plurality of divider terminals, respectively; and a plurality of antenna elements respectively connected with other ends of the plurality of matching circuits. Furthermore, each of the plurality of matching circuits is a lossless circuit having only an inductance component and a capacitance component, and the divider circuit is a lossless circuit whose characteristic impedance is indicated only by the inductance component and the capacitance component, wherein, assuming that a multiplication result is a corrected amplitude phase, the multiplication result being a multiplication result of a ratio of a signal to be given from each of the divider terminals to each of the plurality of matching circuits with respect to a signal to be given from each of the plurality of matching circuits to cach of the plurality of antenna elements, and a desired amplitude phase of a signal to be given to each of the plurality of antenna elements, the divider circuit adjusts an amplitude phase of the signal to be given to each of the plurality of matching circuits in such a way that an amplitude phase of the signal to be given from each of the divider terminals to each of the plurality of matching circuits becomes the corrected amplitude phase.

### Advantageous Effects of Invention

According to the present disclosure, it is possible to suppress consumption of power of a reflected wave, and prevent a gain from lowering.

### BRIEF DESCRIPTION OF DRAWINGS

FIG. 1 is a configuration diagram illustrating an antenna device according to Embodiment 1.

FIG. 2 is a configuration diagram illustrating an example of an internal configuration of a divider circuit 1.

FIG. 3 is a configuration diagram illustrating an example of an internal configuration of a matching circuit 2-n.

FIG. 4 is a configuration diagram illustrating an example of the internal configuration of the matching circuit 2-n.

FIG. 5 is a flowchart illustrating a production method of the antenna device illustrated in FIG. 1.

FIG. 6 is a view for describing circuit operations of N antenna elements 3-1 to 3-N.

FIG. 7 is an explanatory view illustrating a state where an antenna element 3-n is terminated by an active reflection coefficient Γᵢ.

FIG. 8 is an explanatory view illustrating a model to which a design method including a first process to a fourth process has been applied.

FIG. 9 is a configuration diagram illustrating an antenna device according to Embodiment 2.

FIG. 10 is a configuration diagram illustrating an antenna device according to Embodiment 3.

### DESCRIPTION OF EMBODIMENTS

Hereinafter, embodiments for carrying out the present disclosure will be described with reference to the accompanying drawings to describe the present disclosure in more detail.

### Embodiment 1

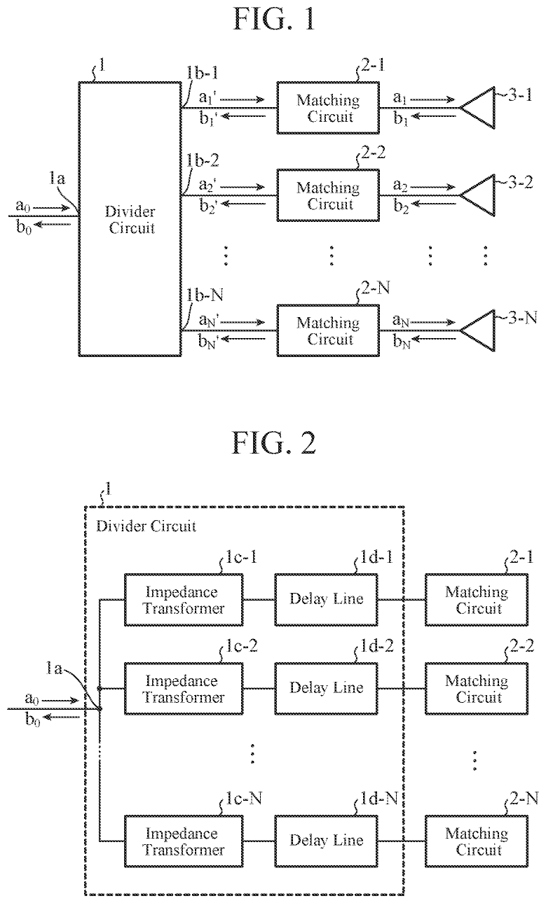

FIG. 1 is a configuration diagram illustrating an antenna device according to Embodiment 1.

The antenna device illustrated in FIG. 1 includes a divider circuit 1, N matching circuits 2-1 to 2-N, and N antenna elements 3-1 to 3-N. N represents an integer equal to or more than two.

In Embodiment 1, an example will be described where the antenna device illustrated in FIG. 1 is used as a transmission antenna that transmits signals. However, the antenna device illustrated in FIG. 1 may be used as a reception antenna that receives signals.

The divider circuit 1 includes an input/output terminal 1a and N divider terminals 1b-1 to 1b-N.

The divider circuit 1 divides power of a signal given from the input/output terminal 1a into N, and outputs the signal subjected to power division from the divider terminal 1b-n (n=1, . . . , N) to the matching circuit 2-N.

When dividing the power of the signal given from the input/output terminal 1a into N, the divider circuit 1 adjusts the amplitude phase of the signal to be given to the matching circuit 2-n in such a way that the amplitude phase of the signal to be given from the divider terminal 1b-n to the matching circuit 2-n becomes a corrected amplitude phase Aₙ′.

The corrected amplitude phase Aₙ′ corresponds to a multiplication result of a ratio αₙ of the signal to be given from the divider terminal 1b-n to the matching circuit 2-n with respect to a signal to be given from the matching circuit 2-n to the antenna element 3-n, and a desired amplitude phase Aₙ of the signal to be given to the antenna element 3-n.

The divider circuit 1 is a lossless circuit whose characteristic impedance is indicated only by an inductance component and a capacitance component. The lossless circuit is a circuit whose resistance component is neglectably small.

As illustrated in FIG. 2, the divider circuit 1 includes, for example, impedance transformers 1c-n (n=1, . . . , N) and delay lines 1d-n. A circuit including the impedance transformers 1c-n and the delay lines 1d-n is a lossless circuit whose characteristic impedance is indicated only by an inductance component and a capacitance component.

FIG. 2 is a configuration diagram illustrating an example of an internal configuration of the divider circuit 1.

One end of the impedance transformer 1c-n is connected with the input/output terminal 1a, and the other end of the impedance transformer 1c-n is connected with one end of the delay line 1d-n.

Examples of the impedance transformer 1c-n of the lossless circuit include an impedance transformer of a system that uses a transformer, and an impedance transformer of a system that uses transmission lines such as micro strip lines.

The one end of the delay line 1d-n is connected with the other end of the impedance transformer 1c-n, and the other end of the delay line 1d-n is connected with one end of the matching circuit 2-n.

As the delay line 1d-n of the lossless circuit, there is a line that has a predetermined length with respect to the wavelength of a signal.

The one end of the matching circuit 2-n (n=1, . . . , N) is connected with the divider terminal 1b-n included in the divider circuit 1, and the other end of the matching circuit 2-n is connected with the antenna element 3-n.

The matching circuit 2-n is a lossless circuit that has only an inductance component and a capacitance component.

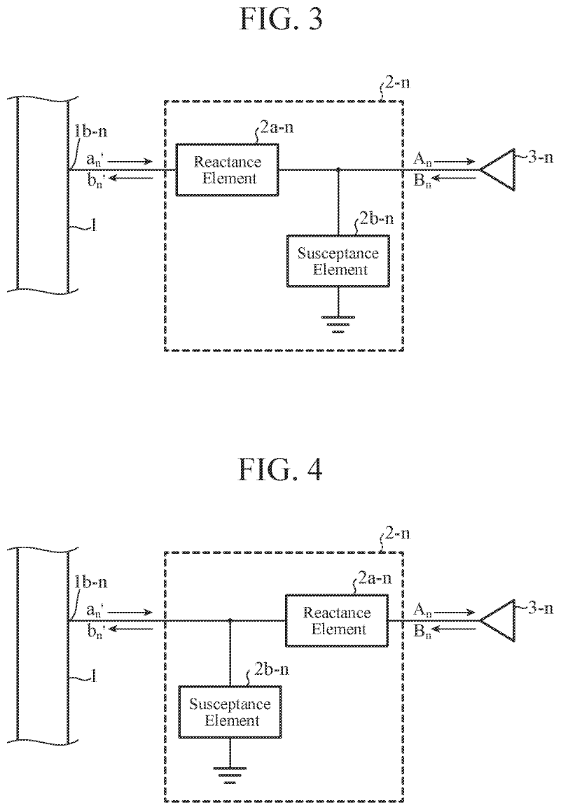

As illustrated in FIG. 3, the matching circuit 2-n includes a reactance element 2a-n and a susceptance element 2b-n. A circuit including the reactance element 2a-n and the susceptance element 2b-n is a lossless circuit that has only an inductance component and a capacitance component.

FIG. 3 is a configuration diagram illustrating an example of an internal configuration of the matching circuit 2-n.

One end of the reactance element 2a-n is connected with the divider terminal 1b-n, and the other end of the reactance element 2a-n is connected with each of the antenna element 3-n and the one end of the susceptance element 2b-n.

One end of the susceptance element 2b-n is connected with each of the other end of the reactance element 2a-n and the antenna element 3-n.

The other end of the susceptance element 2b-n is grounded.

In the matching circuit 2-n illustrated in FIG. 3, the one end of the susceptance element 2b-n is connected with each of the other end of the reactance element 2a-n and the antenna element 3-n. However, this is merely an example, and, as illustrated in FIG. 4, the one end of the susceptance element 2b-n may be connected with each of the one end of the reactance element 2a-n and the divider terminal 1b-n.

FIG. 4 is a configuration diagram illustrating an example of the internal configuration of the matching circuit 2-n.

Next, a production method and an operation of the antenna device illustrated in FIG. 1 will be described.

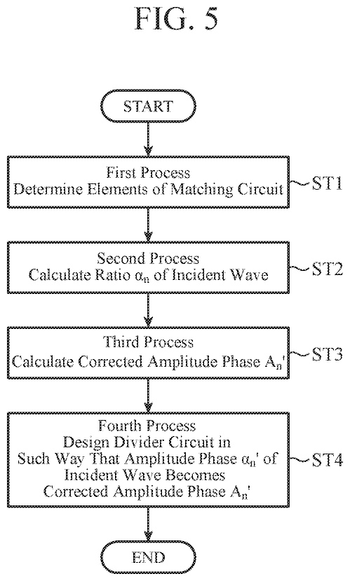

FIG. 5 is a flowchart illustrating the production method of the antenna device illustrated in FIG. 1. The production method of the antenna device illustrated in FIG. 1 includes four processes.

The production method will be described assuming that the antenna device illustrated in FIG. 1 is a transmission antenna.

It is supposed that the amplitude phase of an incident wave that is a signal to be given from the outside to the input/output terminal 1a of the divider circuit 1 is a₀, and the amplitude phase of a reflected wave that is a signal to be output from the input/output terminal 1a to the outside is b₀.

Furthermore, it is supposed that the amplitude phase of an incident wave to be given from the divider terminal 1b-n (n=1, . . . , N) of the divider circuit 1 to the matching circuit 2-n is aₙ′, and the amplitude phase of an incident wave to be given from the matching circuit 2-n to the antenna element 3-n is aₙ.

Furthermore, it is supposed that the amplitude phase of a reflected wave to be given from the antenna element 3-n to the matching circuit 2-n is bₙ, and the amplitude phase of a reflected wave to be given from the matching circuit 2-n to the divider terminal 1b-n of the divider circuit 1 is bₙ′.

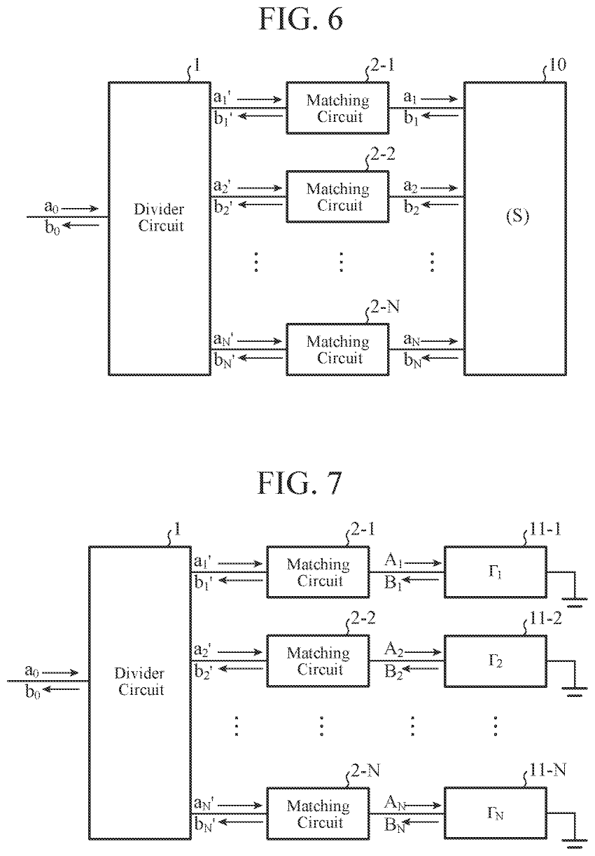

A circuit operation of the N antenna elements 3-1 to 3-N can be expressed as in FIG. 6.

FIG. 6 is an explanatory view illustrating the circuit operation of the N antenna elements 3-1 to 3-N.

In FIG. 6, the symbol 10 represents S parameters.

In a case where a plurality of elements of the S parameters 10 are defined as Sᵢⱼ, the relationship between the amplitude phase aₙ of the incident wave and the amplitude phase bₙ of the reflected wave can be expressed by the following equation (1). i=1, . . . , and N, and j=1, . . . , and N.

$${b}_{1} = {S}_{11} {a}_{1} + {S}_{12} {a}_{2} … … + {S}_{1 N} {a}_{N} \qquad ( 1 )$$

$${b}_{2} = {S}_{21} {a}_{1} + {S}_{22} {a}_{2} … … + {S}_{2 N} {a}_{N}$$

$$⋮$$

$${b}_{N} = {S}_{N 1} {a}_{1} + {S}_{N 2} {a}_{2} … … + {S}_{NN} {a}_{N}$$

To enable the antenna device illustrated in FIG. 1 to obtain a desired radiation pattern, it is requested that the amplitude phase aₙ of the incident wave to be given from the matching circuit 2-n to the antenna element 3-n matches with the desired amplitude phase Aₙ as expressed by the following equation (2).

aₙ=Aₙ (2)

Furthermore, to enable maximization of a gain of the antenna device illustrated in FIG. 1, it is requested that the amplitude phase b₀ of the reflected wave is 0 as expressed by the following equation (3). When the amplitude phase b₀ of the reflected wave is not zero, the gain of the antenna device lowers.

b₀=0 (3)

The divider circuit 1 is designed under a condition of bₙ=0 as described later.

A first process is a process of determining elements of the matching circuit 2-n connected with the antenna element 3-n (n=1, . . . , N) (step ST1 in FIG. 5).

Hereinafter, the process of determining the elements of the matching circuit 2-n will be specifically described.

Substituting aₙ=Aₙ expressed by the equation (2) to the equation (1) transforms the equation (1) to the following equation (4).

$${B}_{1} = {S}_{11} {A}_{1} + {S}_{12} {A}_{2} … … + {S}_{1 N} {A}_{N} \qquad ( 4 )$$

$${B}_{2} = {S}_{21} {A}_{1} + {S}_{22} {A}_{2} … … + {S}_{2 N} {A}_{N}$$

$$⋮$$

$${B}_{N} = {S}_{N 1} {A}_{1} + {S}_{N 2} {A}_{2} … … + {S}_{N N} {A}_{N}$$

In the equation (4), Bₙ is the amplitude phase of the reflected wave to be output from the antenna element 3-n to the matching circuit 2-n when aₙ=Aₙ.

By dividing both sides of the equation (4) by the desired amplitude phase Aₙ, the equation (4) is transformed into the following equation (5).

$$\frac{{B}_{1}}{{A}_{1}} = {S}_{11} + A \frac{{S}_{12} {A}_{2}}{{A}_{1}} + … + \frac{{S}_{1 N} {A}_{N}}{{A}_{1}} \qquad ( 5 )$$

$$\frac{{B}_{2}}{{A}_{2}} = \frac{{S}_{21} {A}_{1}}{{A}_{2}} + {S}_{22} + … + \frac{{S}_{2 N} {A}_{N}}{{A}_{2}}$$

$$⋮$$

$$\frac{{B}_{N}}{{A}_{N}} = \frac{{S}_{N 1} {A}_{1}}{{A}_{N}} + \frac{{S}_{N 2} {A}_{2}}{{A}_{N}} + … + {S}_{N N}$$

The left side of the equation (5) corresponds to an active reflection coefficient at a time when the antenna element 3-n (n=1, . . . , N) is ideally excited.

Bₙ/Aₙ=Γₙ transforms the equation (5) to the following equation (6).

$${Γ}_{1} = {S}_{11} + \frac{{S}_{12} {A}_{2}}{{A}_{1}} + … + \frac{{S}_{1 N} {A}_{N}}{{A}_{1}} \qquad ( 6 )$$

$${Γ}_{2} = \frac{{S}_{21} {A}_{1}}{{A}_{2}} + {S}_{22} + … + \frac{{S}_{2 N} {A}_{N}}{{A}_{2}}$$

$$⋮$$

$${Γ}_{N} = \frac{{S}_{N 1} {A}_{1}}{{A}_{N}} + \frac{{S}_{N 2} {A}_{2}}{{A}_{N}} + … + {S}_{N N}$$

Assuming that a state where the antenna element 3-n (n=1, . . . , N) is ideally excited is kept, and the configuration of the antenna element 3-n does not change, each of Aₙ and Sᵢⱼ in the equation (6) does not change. That is, the antenna element 3-n is illustrated as a circuit that is terminated by the active reflection coefficient Γₙ as illustrated in FIG. 7.

FIG. 7 is an explanatory view illustrating a state where the antenna element 3-n is terminated by the active reflection coefficient Γₙ.

In FIG. 7, 11-n (n=1, . . . , N) represents a reflection termination corresponding to the antenna element 3-n terminated by the active reflection coefficient Γₙ. A reflection coefficient of the reflection termination 11-n is Γₙ.

By designing the matching circuit 2-n (n=1, . . . , N) by the following procedure, the matching circuit 2-n can cancel the reflected wave from the reflection termination 11-n without using the resistance component. In this regard, it is assumed that the numerical value of the reflection coefficient Γₙ of the reflection termination 11-n is less than one.

First, the relationship between the reflection coefficient Γₙ, an active reflection resistance rₙ, and an active reflection reactance xₙ is expressed by the following equation (7).

$${r}_{n} + {jx}_{n} = \frac{1 + {Γ}_{N}}{1 - {Γ}_{N}} \qquad ( 7 )$$

Next, in a case where the reflection coefficient Γₙ (n=1, . . . , N) is located in a first quadrant of a complex plane, the antenna device illustrated in FIG. 1 includes the matching circuit 2-n illustrated in FIG. 3, so that it is possible to adjust to zero the amplitude phase bₙ′ of the reflected wave to be given from the matching circuit 2-n to the divider terminal 1b-n of the divider circuit 1.

That is, the one end of the reactance element 2a-n that is the normalized reactance of the serial element xmₙ expressed by the following equation (8) is connected with the divider terminal 1b-n, and the other end of the reactance element 2a-n is connected with the antenna element 3-n. Furthermore, the one end of the susceptance element 2b-n that is the normalized susceptance of the parallel element ymₙ expressed by the following equation (9) is connected with each of the other end of the reactance element 2a-n and the antenna element 3-n, and the other end of the susceptance element 2b-n is grounded. Consequently, the matching circuit 2-n can adjust the amplitude phase bₙ′ of the reflected wave to zero.

$${xm}_{n} = \frac{- \sqrt{( {r}_{n}^{2} + {x}_{n}^{2} ) {r}_{n} - {r}_{n}^{2}}}{{r}_{n}} \qquad ( 8 )$$

$${ym}_{n} = \frac{{x}_{n} - \sqrt{( {r}_{n}^{2} + {x}_{n}^{2} ) {r}_{n} - {r}_{n}^{2}}}{{r}_{n}^{2} + {x}_{n}^{2}} \qquad ( 9 )$$

In a case where the reflection coefficient Γₙ (n=1, . . . , N) is located in a second quadrant of the complex plane, the antenna device illustrated in FIG. 1 includes the matching circuit 2-n illustrated in FIG. 4, so that it is possible to adjust to zero the amplitude phase bₙ′ of the reflected wave to be given from the matching circuit 2-n to the divider terminal 1b-n of the divider circuit 1.

That is, the one end of the reactance element 2a-n that is the normalized reactance of the serial element xmₙ expressed by the following equation (10) is connected with the divider terminal 1b-n, and the other end of the reactance element 2a-n is connected with the antenna element 3-n. Furthermore, the one end of the susceptance element 2b-n that is the normalized susceptance of the parallel element ymₙ expressed by the following equation (11) is connected with each of the one end of the reactance element 2a-n and the divider terminal 1b-n, and the other end of the susceptance element 2b-n is grounded. Consequently, the matching circuit 2-n can adjust the amplitude phase bₙ′ of the reflected wave to zero.

$$x {m}_{n} = - {x}_{n} + \sqrt{{r}_{n} - {r}_{n}^{2}} \qquad ( 10 )$$

$${ym}_{n} = \frac{\sqrt{{r}_{n} - {r}_{n}^{2}}}{{r}_{n}} \qquad ( 11 )$$

In a case where the reflection coefficient Γₙ (n=1, . . . , N) is located in a third quadrant of the complex plane, the antenna device illustrated in FIG. 1 includes the matching circuit 2-n illustrated in FIG. 4, so that it is possible to adjust to zero the amplitude phase bₙ′ of the reflected wave to be given from the matching circuit 2-n to the divider terminal 1b-n of the divider circuit 1.

That is, the one end of the reactance element 2a-n that is the normalized reactance of the serial element xmₙ expressed by the following equation (12) is connected with the divider terminal 1b-n, and the other end of the reactance element 2a-n is connected with the antenna element 3-n. Furthermore, the one end of the susceptance element 2b-n that is the normalized susceptance of the parallel element ymₙ expressed by the following equation (13) is connected with each of the one end of the reactance element 2a-n and the divider terminal 1b-n, and the other end of the susceptance element 2b-n is grounded. Consequently, the matching circuit 2-n can adjust the amplitude phase bₙ′ of the reflected wave to zero.

$${xm}_{n} = - {x}_{n} - \sqrt{{r}_{n} - {r}_{n}^{2}} \qquad ( 12 )$$

$${ym}_{n} = \frac{- \sqrt{{r}_{n} - {r}_{n}^{2}}}{{r}_{n}} \qquad ( 13 )$$

Next, in a case where the reflection coefficient Γₙ (n=1, . . . , N) is located in a fourth quadrant of the complex plane, the antenna device illustrated in FIG. 1 includes the matching circuit 2-n illustrated in FIG. 3, so that it is possible to adjust to zero the amplitude phase bₙ′ of the reflected wave to be given from the matching circuit 2-n to the divider terminal 1b-n of the divider circuit 1.

That is, the one end of the reactance element 2a-n that is the normalized reactance of the serial element xmₙ expressed by the following equation (14) is connected with the divider terminal 1b-n, and the other end of the reactance element 2a-n is connected with the antenna element 3-n. Furthermore, the one end of the susceptance element 2b-n that is the normalized susceptance of the parallel element ymₙ expressed by the following equation (15) is connected with each of the other end of the reactance element 2a-n and the antenna element 3-n, and the other end of the susceptance element 2b-n is grounded. Consequently, the matching circuit 2-n can adjust the amplitude phase bₙ′ of the reflected wave to zero.

$$x {m}_{n} = \frac{\sqrt{( {r}_{n}^{2} + {x}_{n}^{2} ) {r}_{n} - {r}_{n}^{2}}}{{r}_{n}} \qquad ( 14 )$$

$${ym}_{n} = \frac{{x}_{n} + \sqrt{( {r}_{𝔫}^{2} + {x}_{n}^{2} ) {r}_{n} - {r}_{n}^{2}}}{{r}_{n}^{2} + {x}_{n}^{2}} \qquad ( 15 )$$

In the antenna device illustrated in FIG. 1, the matching circuit 2-n (n=1, . . . , N) is the matching circuit illustrated in FIG. 3 or the matching circuit illustrated in FIG. 4. The matching circuit 2-n only needs to be a lossless circuit, and is not limited to the matching circuit illustrated in FIG. 3 or the matching circuit illustrated in FIG. 4. The matching circuit 2-n may be, for example, a circuit that includes a transmission line that has a characteristic impedance different from those of surrounding lines, an open stub, or a short stub. The circuit that includes the transmission line, the open stub, or the short stub is a lossless circuit that has only an impedance component and a capacitance component.

The antenna device illustrated in FIG. 1 includes the matching circuit 2-n that can adjust the amplitude phase bₙ′ of the reflected wave to zero. However, the amplitude phase bₙ′ of the reflected wave only needs to take a value that is small in such a range that no practical problem occurs, and the matching circuit 2-n is not limited to the matching circuit that can adjust the amplitude phase bₙ′ to zero. The value that is small in such a range that no practical problem occurs is supposed to be approximately 0.1.

The second process is a process of calculating the ratio αₙ (n=1, . . . , N) of the incident wave to be given from the divider terminal 1b-n to the matching circuit 2-n with respect to the incident wave to be given from the matching circuit 2-n to the antenna element 3-n (step ST2 in FIG. 5).

In the matching circuit 2-n illustrated in FIG. 3 or the matching circuit 2-n illustrated in FIG. 4, the S parameter that indicates the characteristics of the matching circuit 2-n is defined as Smᵢⱼₖ (i=1, . . . , and N,j=1, 2). In a case of indices j and k, a number indicating a port on the divider circuit 1 side is one, and a number indicating a port on the antenna element 3-n side is two.

In this case, the relationship between the desired amplitude phase Aₙ of the incident wave to be given to the antenna element 3-n, the amplitude phase aₙ′, the amplitude phase Bₙ of the reflected wave at a time of aₙ=Aₙ, and the amplitude phase bₙ′ of the reflected wave is expressed by the following equation (16).

b′ₙ=Smᵢ₁₁α′ₙ+Smᵢ₁₂Bₙ

Aₙ=Smᵢ₂₁α′ₙ+Smᵢ₁₂Bₙ (16)

Since Bₙ/Aₙ=Γₙ, the ratio αₙ is expressed by the following equation (17).

Consequently, the ratio an can be calculated by using the following equation (17).

$${α}_{n} = \frac{1 - {Sm}_{i 22} {Γ}_{n}}{{Sm}_{i 21}} \qquad ( 17 )$$

The third process is a process of calculating the corrected amplitude phase Aₙ′ (step ST3 in FIG. 5).

The corrected amplitude phase Aₙ′ is expressed by the following equation (18).

Aₙ′αₙAₙ (18)

Consequently, by multiplying the ratio αₙ and the desired amplitude phase Aₙ, the corrected amplitude phase Aₙ′ is obtained.

When the amplitude phase Aₙ′ of the incident wave to be given to the matching circuit 2-n can be adjusted to the corrected amplitude phase Aₙ′, it is possible to adjust the amplitude phase aₙ of the incident wave to be given to the antenna element 3-n to the desired amplitude phase Aₙ.

The fourth process is a process of designing the divider circuit 1 in such a way that the amplitude phase aₙ′ of the incident wave to be given to the matching circuit 2-n (n=1, . . . , N) becomes the corrected amplitude phase Aₙ′ (step ST4 in FIG. 5).

The first process to the third process adjust to zero the amplitude phase bₙ′ of the reflected wave to be given from the matching circuit 2-n to the divider terminal 1b-n of the divider circuit 1. Consequently, in the fourth process, the divider circuit 1 can be designed under a condition where a reflection-free termination is connected. This divider circuit 1 can be designed using the impedance transformer 1c-n and the delay line 1d-n as illustrated in FIG. 2.

The impedance transformer 1c-n (n=1, . . . , N) adjusts an impedance at the impedance transformer 1c-n seen from the input/output terminal 1a in proportion to a reciprocal of a square of |Aₙ′|, so that the divider circuit 1 can perform power division with the desired amplitude. |Aₙ′| represents the amplitude of the corrected amplitude phase Aₙ′.

A proportional coefficient of the above proportion can be selected at random, so that the above impedance can be adjusted to achieve non-reflectiveness when the N lines are combined. That is, the above impedance can be adjusted in such a way that b₀=0.

Furthermore, ∠Aₙ′ is defined as an argument of the corrected amplitude phase Aₙ′. In a case where a maximum value is ∠Aₘₐₓ among ∠A₁′ to ∠A_{N}′, ∠Aₙ′-∠Aₘₐₓ takes a value equal to or less than zero with respect to all of the plurality of antenna elements 3-1 to 3-N, and consequently can be achieved by a delay line.

The length of the delay line 1d-n connected to the antenna element 3-n (n=1, . . . , N) is selected in such a way as to become |∠Aₙ-∠Aₘₐₓ|/k₀, so that it is possible to obtain a desired delay amount. In this regard, k₀ is a wavenumber of the delay line 1d-n.

By designing the divider circuit 1 as described above, it is possible to adjust the amplitude phase aₙ′ of the incident wave to be given to the matching circuit 2-n (n=1, . . . , N) to the corrected amplitude phase Aₙ′.

In the antenna device illustrated in FIG. 1, the divider circuit 1 includes the impedance transformers 1c-n and the delay lines 1d-n as illustrated in FIG. 2. The divider circuit 1 may be a divider circuit different from that in FIG. 2 as long as the divider circuit is a lossless circuit and can change the phase. For example, instead of the delay lines 1d-n, a T-type phase shifter or a π type phase shifter that uses a lumped constant may be used as means that changes the phase.

By designing the antenna device according to the first process to the fourth process, it is possible to give the desired amplitude phase Aₙ to the antenna element 3-n, (n=1, . . . , N), and adjust to zero the amplitude phase bo of the reflected wave from the input/output terminal 1a.

Furthermore, this antenna device can be designed as a lossless circuit. As a result, desired radiation characteristics of the antenna device can be obtained, and there is no loss of the divider circuit 1, so that it is possible to obtain an advantage of improvement of an antenna gain.

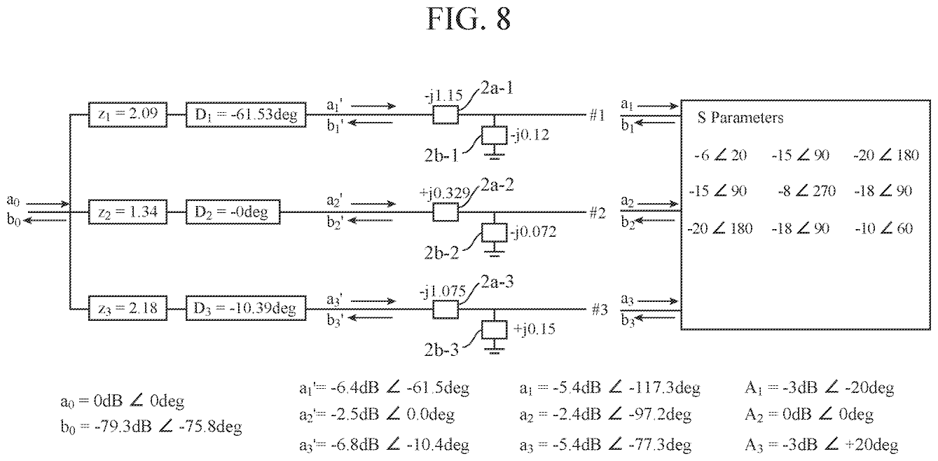

FIG. 8 is an explanatory view illustrating a model to which a design method including the first process to the fourth process is applied.

The model illustrated in FIG. 8 assumes a three-element array, and is given the S parameters and desired amplitude phases A₁, A₂, and A₃.

The model illustrated in FIG. 8 includes a ¼ wavelength impedance transformer that has a normalized impedance z₁, a ¼ wavelength impedance transformer that has a normalized impedance z₂, and a ¼ wavelength impedance transformer that has a normalized impedance z₃ as the impedance transformers 1c-1 to 1c-3.

Furthermore, the model illustrated in FIG. 8 includes a delay line of a phase amount D₁, a delay line of a phase amount D₂, and a delay line of a phase amount D₃ as the delay lines 1d-n.

Furthermore, the model illustrated in FIG. 8 includes reactance elements 2a-1 to 2a-3 and susceptance elements 2b-1 to 2b-3 as the matching circuits 2-1 to 2-3.

Furthermore, the model illustrated in FIG. 8 includes the S parameters obtained by simulating the plurality of antenna elements 3-1 to 3-3.

Each of a₁, a₂, and a₃ illustrated in FIG. 8 is a result obtained by calculating an amplitude phase of an incident wave to be given to the plurality of antenna elements 3-1 to 3-3 when circuit characteristics of the model illustrated in FIG. 8 are simulated.

Upon comparison between the amplitude phase aₙ (n=1, 2, and 3) and the desired amplitude phase Aₙ (n=1, 2, and 3), it is possible to check that the amplitude of the amplitude phase aₙ is offset from the amplitude of the desired amplitude phase Aₙ, and the phase of the amplitude phase aₙ is offset from the phase of the desired amplitude phase Aₙ. This is because the amplitude of an incident wave ao is normalized to one, and the phase of the incident wave a₀ is normalized to zero. The offsets at the amplitude and the phase do not influence the radiation characteristics of the antenna device. Hence, it is possible to check that, when the influence of these offsets is not taken into account, the amplitude phase aₙ (n=1, 2, and 3) and the desired amplitude phase Aₙ (n=1, 2, and 3) are substantially equal.

Furthermore, the amplitude of the amplitude phase bo of the reflected wave is −79 dB, and a sufficiently small value is obtained. In view of the above, it has been checked that desired characteristics can be obtained.

According to above Embodiment 1, the antenna device is configured to include the divider circuit 1 that includes the input/output terminal 1a and the plurality of divider terminals 1b-1 to 1b-N, the plurality of matching circuits 2-1 to 2-N that include the one ends connected with the divider terminals 1b-n (n=1, . . . , N), and the plurality of antenna elements 3-1 to 3-N that are connected with the other ends of the matching circuits 2-n. Furthermore, the matching circuit 2-n included in the antenna device is configured as the lossless circuit that has only an inductance component and a capacitance component, and the divider circuit 1 included in the antenna device is configured as the lossless circuit whose characteristic impedance is indicated only by the inductance component and the capacitance component. Consequently, the antenna device can suppress consumption of power of the reflected wave, and prevent the gain from lowering.

### Embodiment 2

Embodiment 2 will describe an antenna device in which a serial circuit 20-n in which a phase shifter 21-n (n=1, . . ., N) and an amplifier 22-n are connected in series is inserted between the divider circuit 1 and the matching circuit 2-n.

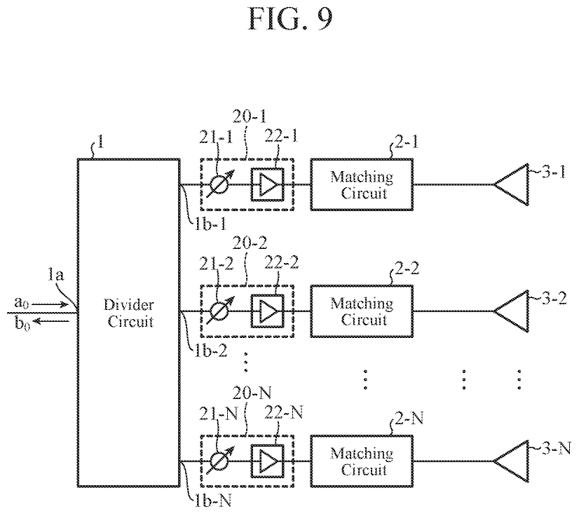

FIG. 9 is a configuration diagram illustrating the antenna device according to Embodiment 2. In FIG. 9, the same reference numerals as those in FIG. 1 denote the same or corresponding components, and therefore description thereof will be omitted.

The antenna device illustrated in FIG. 9 includes the divider circuit 1, the N serial circuits 20-1 to 20-N, the N matching circuits 2-1 to 2-N, and the N antenna elements 3-1 to 3-N. N represents an integer equal to or more than two.

Embodiment 2 will describe an example where the antenna device illustrated in FIG. 9 is used as a transmission antenna that transmits signals. However, the antenna device illustrated in FIG. 9 may be used as a reception antenna that receives signals.

The serial circuit 20-n (n=1, . . . , N) is inserted between the divider circuit 1 and the matching circuit 2-n.

The serial circuit 20-n includes the phase shifter 21-n and the amplifier 22-n.

The one end of the phase shifter 21-n is connected with the divider terminal 1b-n of the divider circuit 1, and the other end of the phase shifter 21-n is connected with the one end of the amplifier 22-n.

The one end of the amplifier 22-n is connected with the other end of the phase shifter 21-n, and the other end of the amplifier 22-n is connected with the one end of the matching circuit 2-n.

In the antenna device illustrated in FIG. 9, the phase shifter 21-n is provided at a stage before the amplifier 22-n. However, this is merely an example, and the phase shifter 21-n may be provided at a stage after the amplifier 22-n.

Next, a production method and an operation of the antenna device illustrated in FIG. 9 will be described.

Unlike the antenna device illustrated in FIG. 1, in the antenna device illustrated in FIG. 9, the serial circuit 20-n is inserted between the divider circuit 1 and the matching circuit 2-n (n=1, . . . , N).

Hence, a fourth process for generating the antenna device illustrated in FIG. 9 is different from the fourth process for generating the antenna device illustrated in FIG. 1.

The divider circuit 1 has a function of equally dividing an incident wave to be given from the outside to the input/output terminal 1a in a non-reflective manner. That is, the divider circuit 1 has a function of adjusting the amplitude phase b₀ of a reflected wave to zero when equally dividing the incident wave.

The phase of the amplitude phase an (n=1, . . . , N) of the incident wave equally divided by the divider circuit 1 is adjusted to the phase of the corrected amplitude phase Aₙ′ by the phase shifter 21-n.

The amplitude of the amplitude phase aₙ of the incident wave is adjusted to the amplitude of the corrected amplitude phase Aₙ′ by the amplifier 22-n.

Accordingly, the antenna device illustrated in FIG. 9, the divider circuit 1 only needs to have a function of equally dividing the incident wave in a non-reflective manner, and may not have a function of adjusting the amplitude phase aₙ′ of the incident wave to the corrected amplitude phase Aₙ′.

The antenna device illustrated in FIG. 9 is also applicable to an antenna device of a type that uses a high frequency module.

In the antenna device illustrated in FIG. 9, the serial circuit 20-n is inserted between the divider circuit 1 and the matching circuit 2-n. The circuit inserted between the divider circuit 1 and the matching circuit 2-n only needs to be a circuit that has a function of adjusting the amplitude phase aₙ′ of the incident wave to the corrected amplitude phase Aₙ′, and is not limited to the serial circuit 20-n.

### Embodiment 3

Embodiment 3 will describe an antenna device that includes a control unit 33.

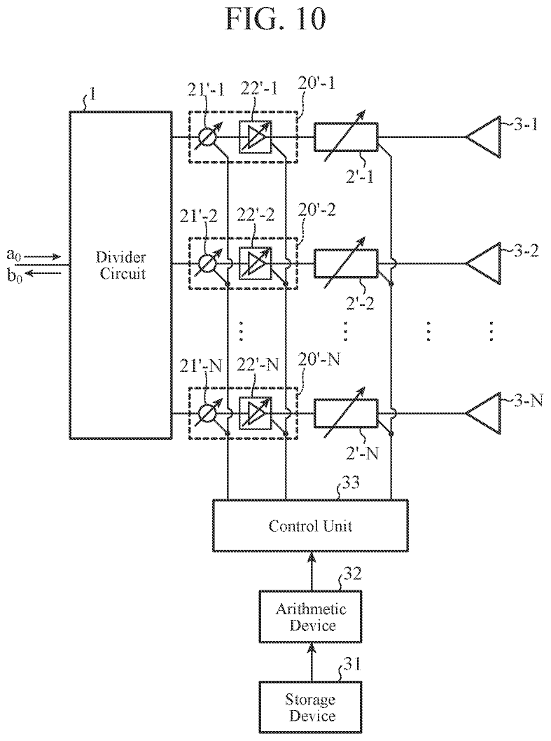

FIG. 10 is a configuration diagram illustrating the antenna device according to Embodiment 3. In FIG. 10, the same reference numerals as those in FIG. 9 denote the same or corresponding components, and therefore description thereof will be omitted.

In the antenna device illustrated in FIG. 10, the matching circuit 2-n (n=1, . . . , N) is a variable matching circuit 2′-n.

Furthermore, in the antenna device illustrated in FIG. 10, the serial circuit 20-n is a serial circuit 20′-n, and the serial circuit 20′-n includes a variable phase shifter 21′-n and a variable amplifier 22′-n.

The antenna device illustrated in FIG. 10 includes the divider circuit 1, N serial circuits 20′-1 to 20′-N, N variable matching circuits 2′-1 to 2′-N, the N antenna elements 3-1 to 3-N, a storage device 31, an arithmetic device 32, and the control unit 33.

The storage device 31 is implemented as, for example, a non-volatile or volatile semiconductor memory such as a Random Access Memory (RAM), a Read Only Memory (ROM), a flash memory, an Erasable Programmable Read Only Memory (EPROM), and an Electrically Erasable Programmable Read Only Memory (EEPROM), a magnetic disk, a flexible disk, an optical disk, a compact disc, a mini disk, or a Digital Versatile Disc (DVD).

The storage device 31 stores a desired antenna radiation pattern in addition to the S parameter of the antenna element 3-n (n=1, ... , N).

The arithmetic device 32 is implemented as, for example, an arithmetic circuit.

The arithmetic device 32 calculates the desired amplitude phase Aₙ of the antenna element 3-n (n=1, . . . , N) on the basis of the desired antenna radiation pattern stored in the storage device 31.

Furthermore, the arithmetic device 32 calculates each of elements of the variable matching circuit 2′-n and the corrected amplitude phase Aₙ′ on the basis of the S parameter stored in the storage device 31 and the desired amplitude phase Aₙ.

Calculation processing of the amplitude phase Aₙ performed by the arithmetic device 32 is a known technique, and therefore detailed description thereof will be omitted.

Furthermore, each of calculation processing of the elements of the variable matching circuit 2′-n and calculation processing of the corrected amplitude phase Aₙ′ performed by the arithmetic device 32 is the same as the first process to the fourth process in the antenna device according to Embodiment 2, and therefore detailed description thereof will be omitted.

The control unit 33 is implemented as, for example, a control circuit.

The control unit 33 controls the variable matching circuit 2′-n in such a way that the elements of the variable matching circuit 2′-n (n=1, . . . , N) becomes the elements of the variable matching circuit 2′-n calculated by the arithmetic device 32.

The control unit 33 controls the variable phase shifter 21′-n in such a way that the phase subjected to phase adjustment by the variable phase shifter 21′-n becomes the phase of the corrected amplitude phase Aₙ′ calculated by the arithmetic device 32.

Furthermore, the control unit 33 controls the variable amplifier 22′-n in such a way that the amplitude subjected to amplitude adjustment by the variable amplifier 22′-n becomes the amplitude of the corrected amplitude phase Aₙ′ calculated by the arithmetic device 32.

Each of the arithmetic circuit and the control circuit corresponds to, for example, a single circuit, a composite circuit, a programmed processor, a parallel programmed processor, an Application Specific Integrated Circuit (ASIC), a Field-Programmable Gate Array (FPGA), or a combination of these.

The antenna device illustrated in FIG. 10 may be used as a transmission antenna that transmits signals, or may be used as a reception antenna that receives signals.

In the antenna device illustrated in FIG. 10, the control unit 33 controls each of the variable phase shifter 21′-n, the variable amplifier 22′-n, and the variable matching circuit 2′-n. Consequently, unlike the antenna device illustrated in FIG. 9, the antenna device illustrated in FIG. 10 can obtain a desired antenna radiation pattern even when each of elements of the matching circuits, phase amounts of the phase shifters, and amplitude adjustment amounts of the amplifiers are not determined in advance.

Note that, in the present disclosure, free combination of the embodiments, deformation of random components of each embodiment, or omission of random components in each embodiment is possible.

### INDUSTRIAL APPLICABILITY

The present disclosure is suitable for an antenna device that includes a plurality of antenna elements.

### REFERENCE SIGNS LIST

1: divider circuit, 1a: input/output terminal, 1b-1 to 1b-N: divider terminal, 1c-1 to 1c-N: impedance transformer, 1d-1 to 1d-N: delay line, 2-1 to 2-N: matching circuit, 2a-1 to 2a-N: reactance element, 2b-1 to 2b-N: susceptance element, 2′-1 to 2′-N: variable matching circuit, 3-1 to 3-N: antenna element, 10: S parameter, 11: reflection termination, 20-1 to 20-N: serial circuit, 20′-1 to 20′-N: serial circuit, 21-1 to 21-N: phase shifter, 21′-1 to 21′-N: variable phase shifter, 22-1 to 22-N: amplifier, 22′-1 to 22′-N: variable amplifier, 31: storage device, 32: arithmetic device, 33: control unit

1. An antenna device comprising:
a divider circuit including an input/output terminal and a plurality of divider terminals;
a plurality of matching circuits respectively having one ends connected with the plurality of divider terminals, respectively; and
a plurality of antenna elements respectively connected with other ends of the plurality of matching circuits, wherein
each of the plurality of matching circuits is a lossless circuit having only an inductance component and a capacitance component, and
the divider circuit is a lossless circuit whose characteristic impedance is indicated only by the inductance component and the capacitance component,
wherein, assuming that a multiplication result is a corrected amplitude phase, the multiplication result being a multiplication result of a ratio of a signal to be given from each of the divider terminals to each of the plurality of matching circuits with respect to a signal to be given from each of the plurality of matching circuits to each of the plurality of antenna elements, and a desired amplitude phase of a signal to be given to each of the plurality of antenna elements,
the divider circuit adjusts an amplitude phase of the signal to be given to each of the plurality of matching circuits in such a way that an amplitude phase of the signal to be given from each of the divider terminals to each of the plurality of matching circuits becomes the corrected amplitude phase.

2. The antenna device according to claim 1, wherein the divider circuit includes
a plurality of impedance transformers including one ends connected with the input/output terminal; and
a plurality of delay lines including one ends connected with other ends of the impedance transformers, respectively, and other ends connected with one ends of the plurality of matching circuits, respectively.

3. The antenna device according to claim 1, wherein each of the plurality of matching circuits includes
a reactance element including one end connected with each of the divider terminals, and another end connected with each of the plurality of antenna elements, and
a susceptance element including one end connected with the one end of the reactance element or said another end of the reactance element, and another end that is grounded.

4. The antenna device according to claim 3, wherein
the number of the plurality of antenna elements is N, a Scattering (S) parameter between the plurality of antenna elements is Sᵢⱼ (i=1, . . . , N, and j=1, . . . , N), and the desired amplitude phase of the signal to be given to each of the plurality of antenna elements is Aₙ (n=1, . . ., N),
when the signal having the desired amplitude phase is given to each of the plurality of antenna elements, a ratio of a signal reflected by each of the plurality of antenna elements with respect to the signal having the desired amplitude phase is Γₙ (i=1, . . . , N),
each of the reactance element and the susceptance element has an active reflection resistance and an active reflection reactance, the active reflection resistance is rₙ (n=1, . . . , N), and the active reflection reactance is xₙ (n=1, . . . , N),
a ratio of a signal to be given from the divider circuit to each of the plurality of matching circuits with respect to a signal to be given from each of the plurality of matching circuits to each of the plurality of antenna elements is αₙ (n=1, . . . , N),
the S parameters indicating characteristics of each of the plurality of matching circuits are Smᵢⱼₖ (i=1, . . . , N, j=1, 2, and k=1, 2), in which each of the indices j and k being 1 indicates a port on a side of the divider circuit and being 2 indicates a port on a side of each of the plurality of antenna elements, and the corrected amplitude phase is Aₙ′ (n=1, . . . , N),
in a case where the ratio Γₙ is expressed by the equation (1), a relationship between the active reflection resistance rₙ, the active reflection reactance xₙ, and the ratio Γₙ is expressed by the equation (2), and the ratio αₙ is expressed by the equation (3), the corrected amplitude phase Aₙ′ is expressed by the equation (4), and
the active reflection resistance rₙ is adjusted to 1, and the active reflection reactance Xₙ is adjusted to 0.
$${Γ}_{n} = \frac{{S}_{i 1} {A}_{1}}{{A}_{n}} + \frac{{S}_{i 2} {A}_{2}}{{A}_{n}} + … + \frac{{S}_{iN} {A}_{N}}{{A}_{n}} \qquad ( 1 )$$
$${r}_{n} + {jx}_{n} = \frac{1 + {Γ}_{n}}{1 - {Γ}_{n}} \qquad ( 2 )$$
$${α}_{n} = \frac{1 - S {m}_{i 22} {Γ}_{n}}{S {m}_{i 21}} \qquad ( 3 )$$
$${A}_{n}^{′} = {α}_{n} {A}_{n} \qquad ( 4 )$$

5. The antenna device according to claim 4, wherein, in each of the plurality of matching circuits, in a case where the ratio Γₙ is located in a first quadrant of a complex plane, the one end of the reactance element that is a normalized reactance of a serial element xmₙ (n=1, . . . , N) expressed by the equation (5) is connected with each of the divider terminals included in the divider circuit, said another end of the reactance element is connected with each of the plurality of antenna elements, the one end of the susceptance element that is a normalized susceptance of a parallel element ymₙ (n=1, . . . , N) expressed by the equation (6) is connected with each of the plurality of antenna elements, and said another end of the susceptance element is grounded.
$${xm}_{n} = \frac{- \sqrt{( {r}_{n}^{2} + {x}_{n}^{2} ) {r}_{n} - {r}_{n}^{2}}}{{r}_{n}} \qquad ( 5 )$$
$${ym}_{n} = \frac{{x}_{n} - \sqrt{( {r}_{n}^{2} + {x}_{n}^{2} ) {r}_{n} - {r}_{n}^{2}}}{{r}_{n}^{2} + {x}_{n}^{2}} \qquad ( 6 )$$

6. The antenna device according to claim 4, wherein, in each of the plurality of matching circuits, in a case where the ratio Γₙ is located in a second quadrant of a complex plane, the one end of the reactance element that is a normalized reactance of a serial element xmₙ (n=1, . . . , N) expressed by the equation (7) is connected with each of the divider terminals included in the divider circuit, said another end of the reactance element is connected with each of the plurality of antenna elements, the one end of the susceptance element that is a normalized susceptance of a parallel element ymₙ (n=1, . . . , N) expressed by the equation (8) is connected with each of the divider terminals, and said another end of the susceptance element is grounded.
$$x {m}_{n} = - {x}_{n} + \sqrt{{r}_{n} - {r}_{n}^{2}} \qquad ( 7 )$$
$${ym}_{n} = \frac{\sqrt{{r}_{n} - {r}_{n}^{2}}}{{r}_{n}} \qquad ( 8 )$$

7. The antenna device according to claim 4, wherein, in each of the plurality of matching circuits, in a case where the ratio Γₙ is located in a third quadrant of a complex plane, the one end of the reactance element that is a normalized reactance of a serial element xmₙ (n=1, . . . , N) expressed by the equation (9) is connected with each of the divider terminals included in the divider circuit, said another end of the reactance element is connected with each of the plurality of antenna elements, the one end of the susceptance element that is a normalized susceptance of a parallel element ymₙ (n=1, . . . , N) expressed by the equation (10) is connected with each of the divider elements, and said another end of the normalized susceptance element is grounded.
$$x {m}_{n} = - {x}_{n} - \sqrt{{r}_{n} - {r}_{n}^{2}} \qquad ( 9 )$$
$${ym}_{n} = \frac{- \sqrt{{r}_{n} - {r}_{n}^{2}}}{{r}_{n}} \qquad ( 10 )$$

8. The antenna device according to claim 4, wherein, in each of the plurality of matching circuits, in a case where the ratio Γₙ is located in a fourth quadrant of a complex plane, the one end of the reactance element that is a normalized reactance of a serial element xmₙ (n=1, . . . , N) expressed by the equation (11) is connected with each of the divider terminals included in the divider circuit, said another end of the reactance element is connected with each of the plurality of antenna elements, the one end of the susceptance element that is a normalized susceptance of a parallel element ymₙ (n=1, . . . , N) expressed by the equation (12) is connected with each of the plurality of antenna elements, and said another end of the susceptance element is grounded.
$${xm}_{n} = \frac{\sqrt{( {r}_{n}^{2} + {x}_{n}^{2} ) {r}_{n} - {r}_{n}^{2}}}{{r}_{n}} \qquad ( 11 )$$
$${ym}_{n} = \frac{{x}_{n} + \sqrt{( {r}_{n}^{2} + {x}_{n}^{2} ) {r}_{n} - {r}_{n}^{2}}}{{r}_{n}^{2} + {x}_{n}^{2}} \qquad ( 12 )$$

9. The antenna device according to claim 1, wherein a serial circuit in which a phase shifter and an amplifier are connected in series is inserted between the divider circuit and each of the plurality of matching circuits.

10. The antenna device according to claim 9, further comprising a controller to control each of the phase shifter, the amplifier, and the plurality of matching circuits.
